(19) United States
(12) Patent Application Publication
(10) Pub. No.: US 2015/0136211 A1
(43) Pub. Date: May 21, 2015

(54) SOLAR CELL CONTAINING N-TYPE DOPED SILICON

(71) Applicants: APOLLON SOLAR, Lyon (FR); THE AUSTRALIAN NATIONAL UNIVERSITY, Acton, Australian Capital Territory (AU)

(72) Inventors: Maxime Forster, Lyon (FR); Roland Einhaus, Bourgoin Jallieu (FR); Andres Cuevas, Griffith (AU)

(21) Appl. No.: 14/400,690

(22) PCT Filed: Feb. 28, 2013
(86) PCT No.: PCT/FR2013/000056

§ 371 Date: Nov. 12, 2014

(30) Foreign Application Priority Data
May 11, 2012 (FR) 12/01382

(51) Int. Cl. H01L 31/0288; H01L 31/075; H01L 31/068

(52) U.S. Cl. CPC H01L 31/0288; H01L 31/068; H01L 31/075
USPC 136/255

(57) ABSTRACT

A photovoltaic device includes a first semiconducting area having an N-doped silicon base and a second semiconducting area having a P-doped silicon base. The two semiconducting areas are configured to form a PN junction. The first semiconducting area is devoid of boron and includes a concentration of P-type doping impurities that is at least equal to 20% of the concentration of N-type doping impurities.

### BACKGROUND OF THE INVENTION

The invention relates to a solar cell provided with an area made from N-doped silicon forming a PN junction with an area made from P-doped silicon.

### STATE OF THE ART

In the field of photovoltaic devices, there is commonly a junction of PN type which is formed in a semiconductor material and which is biased. A part of the photons captured by the semiconductor material is transformed into electron-hole pairs, which induces an electric current inside the photovoltaic device.

A considerable amount of work is being carried out in order to increase the conversion efficiency of photovoltaic devices, i.e. to increase the quantity of electric energy produced for a given quantity of incident light energy. However, the improvements obtained also have to be able to be easily integrated, with a moderate integration cost so as to limit the final price of the photovoltaic device.

### OBJECT OF THE INVENTION

It is observed that a requirement exists to provide photovoltaic devices presenting improved performances while at the same time continuing to be simple and inexpensive to produce.

This object tends to be achieved by means of a photovoltaic device which comprises:
a first semiconducting area made from N-doped silicon,
a second semiconducting made from P-doped silicon and configured to form a PN or PIN junction with the first semiconducting area,

and wherein the first semiconducting area comprises a concentration of P-type doping impurities that is at least equal to 20% of the concentration of N-type doping impurities.

### BRIEF DESCRIPTION OF THE DRAWINGS

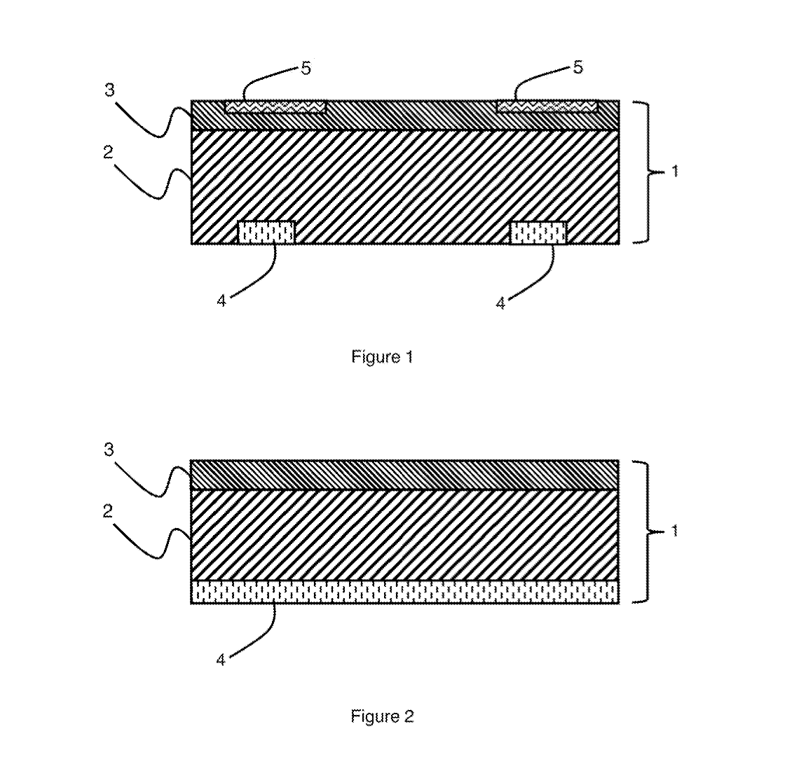

Other advantages and features will become more clearly apparent from the following description of particular embodiments of the invention given for non-restrictive example purposes only and represented in the appended drawings, in which FIGS. 1 and 2 represent two photovoltaic devices in schematic manner, in cross-section.

### DESCRIPTION OF PREFERRED EMBODIMENTS

As illustrated in FIGS. 1 and 2, photovoltaic cell 1 is produced from silicon, i.e. it comprises at least 50% of silicon in the semiconducting areas. In even more preferential manner, it comprises at least a first semiconducting area 2 also called substrate. This first semiconducting area 2 is silicon-based and is N-doped. N-type doping can be obtained by adding one or more electrically doping impurities. These N-type doping impurities are advantageously chosen from P, As, Sb, and Li.

Photovoltaic cell 1 also comprises a second silicon-based semiconducting area 3. This second semiconducting area 3 is P-doped and it is arranged such as to form a PN junction or a PIN junction with first N-type semi-conducting area 2. The P-type second semiconducting area 3 is doped with electrically doping impurities advantageously chosen from B, Ga, In, Al, and Ti. In a particularly advantageous embodiment, the first semiconducting area has a thickness at least equal to 1 micrometre or it represents the largest part of the semiconductor volume of the solar cell.

In advantageous manner, P-type second semiconducting area 3 is devoid of boron atoms, i.e. the boron concentration is less than 10 ppba. In an alternative embodiment, the concentration of boron atoms is less than 0.2 ppma. This low boron concentration enables the effects of Light Induced Degradation on lifetime to be limited.

In a particular embodiment, first N-type semiconducting area 2 has a much larger thickness than second P-type semiconducting area 3. In comparison with a solar cell having a first P-type semiconducting area 2, the use of an first N-type semiconducting area 2 enables the electric impact of the crystal defects and of the metallic impurities also called metallic contaminants, such as for example iron, to be limited. It seems that this improvement of the electric characteristics can be explained by the smaller effective capture cross-section for the electron holes than for the electrons.

In preferential manner, photovoltaic device 1 is arranged in such a way that the radiation to be collected enters via second semiconducting area 3. However, it is also possible to make the incident radiation enter via the opposite surface. In particularly advantageous manner, the major part of the electrically active photovoltaic device 1 is formed by an N-doped material which limits the extent of parasite degrading phenomena under lighting and of impairment of the electric property linked to the metallic impurities. In a particular embodiment, an initial N-doped substrate is provided and is then doped to form a P-type area and the associated PN junction. In order to facilitate formation of the solar cell, the P-doped area is less extensive than the N-doped area in the initial substrate.

In a particularly advantageous embodiment, first semiconducting area 2, which is for the major part N-type, is also doped with P-type doping impurities which are preferably chosen from Ga, Al, In, Ti. First semi-conducting area 2 is co-doped, i.e. it comprises P-type and N-type doping impurities in similar proportions.

In first semiconducting area 2, the concentration of P-type doping impurities is at least equal to 20% of the concentration of N-type doping impurities. The inventors discovered that this embodiment enables the diffusivity of the minority carriers to be reduced thereby enabling recombinations of minority carriers to be limited. This effect is expressed by a considerable increase of the lifetime of the carriers in the photovoltaic device which enables the conversion efficiency of the device to be increased. The photovoltaic cell formed by means of this semiconductor substrate presents a voltage between the two opposite faces which is increased in comparison with a cell according to the prior art.

For example purposes, when the PN junction is arranged in proximity to the front surface of the substrate, co-doping of first semiconducting area 2 enables recombination of the minority carriers on the rear surface to be limited.

The use of a co-doped first semiconducting area 2, i.e. simultaneously presenting P-type and N-type electric dopants in appreciably equivalent proportions, is particularly advantageous as it enables the conversion efficiency of the cell to be increased in inexpensive manner.

In advantageous manner, the co-doped part of first semiconducting area 2 extends from the interface between the first and second semiconducting areas (the PN junction) up to the opposite surface of first semiconducting area 2 where contact connections are located. The contact connections can be achieved by one or more metal bumps or by an electrically conducting layer. The contact connections are designed to output electric current from the photovoltaic device. For example purposes, the contacts can be arranged on the front surface and on the rear surface.

In preferential manner, second semiconducting area 3 is devoid of boron atoms or the concentration of boron atoms is less than 0.02 ppma. This particularity enables the efficiency of the photovoltaic device to be further increased.

In a particular embodiment, first N-type semiconducting area 2 also comprises doped portions 4 and more particularly more strongly doped portions which open onto the rear surface of the substrate so as to facilitate electric contact of the electric device via the rear surface. Doped portions 4 have a concentration of P-type doping impurities that is less than 20% of the concentration of N-type doping impurities. In this way, at the surface of the semiconductor material there are first portions which have a concentration of P-type doping impurities that is at least equal to 20% of the concentration of N-type doping impurities and second portions which have a concentration of P-type doping impurities that is less than 20% of the concentration of N-type doping impurities. There are therefore two types of portions with different resistivity values which open out onto the surface of the semiconductor material. In advantageous manner, the concentration of P-type dopants is identical in the two adjacent N-type portions. It is advantageous to make the electric contact connection in the second portions 4 on account of the fact that the resistivity is reduced.

In another embodiment, first N-type semiconducting area 2 comprises a single doped portion 4 which covers the whole of a main surface of the substrate. The opposite surface of the first portion forms the PN junction. In this configuration, the structure can be represented in the following manner P/N/N+.

Doped portion 4 represents a small thickness of the cell so that if the proportion of P-type dopants is smaller than the proportion of P-type dopants in the first semiconducting area, the influence is negligible. Generally, doped portion 4 has a thickness smaller than or equal to 1 micron.

For example, for a solar cell having a first semiconducting area 2 that is N-doped, almost exclusively by phosphorus at a concentration equal to 0.1 ppm, it is advantageous to have a doping of opposite type for example by gallium at a concentration at least equal to 0.02 ppma. This solar cell presents an increased lifetime of the minority carriers which enables an improved efficiency to be achieved in comparison with a solar cell without P-type doping of first semiconducting area 2.

This particular photovoltaic cell presents good results for different doping levels, in particular in the 0.001-0.01 ppma of phosphorus range, which corresponds to a very weakly doped photovoltaic cell. Good results have also been obtained for a photovoltaic cell having a phosphorus concentration comprised between 0.01 ppma and 0.1 ppma, which corresponds to a medium-doped photovoltaic cell.

Equivalent results were obtained for strongly doped photovoltaic cells, i.e. for a cell having a phosphorus concentration comprised between 0.1 and 1 ppma. Surprisingly, a very strongly doped photovoltaic cell also showed very good results when the phosphorus concentration in the first semi-conducting area is comprised between 1 and 10 ppma.

The results indicated in the foregoing are illustrated for phosphorus doping, but they can be extended for any other N-type electronic dopant and for a combination of the latter. This results in this particular photovoltaic cell being able to be implemented with electronic grade silicon, solar grade silicon or even purified metallurgical grade silicon. It becomes possible to improve the conversion efficiency of the cell at low cost.

Whereas it is commonly admitted that the lifetime of the minority carriers decreases progressively as the concentration of electrically active impurities increases, a means has been discovered for preserving an acceptable lifetime of the carriers in a photovoltaic device even when the photovoltaic cell contains a high total concentration of doping impurities.

First semiconducting area 2 can be single-crystal or multi-crystalline. Second semiconducting area 3 can be single-crystal or multi-crystalline. In advantageous manner, the two semiconducting areas present the same crystallinity. It can also be envisaged to have one or two semiconducting areas in amorphous state so as to form a photovoltaic cell with a hetero-junction.

It is advantageous to form a second P-type semiconducting area 3 having a concentration of N-type dopants that is less than 10% of the concentration of P-type dopants.

There again, it is advantageous to form one or more super-doped areas 5 which open onto the surface of layer 3 in order to facilitate electric contact connection (FIG. 1). Doped area 5 is of the same type of conductivity as second semiconducting layer 3, i.e. doped area 5 is P-type with a lower resistivity than the rest of second semiconducting layer 3. Depending on the embodiments used, the doped area can cover a whole surface of the substrate or form one or more areas.

In a particularly advantageous embodiment, the first and second semi-conducting areas are formed from a single block of semiconductor material in order to limit the interfaces which reduce the global electric performances of the device in a direction perpendicular to the applied electric field. In even more advantageous manner, this block of semiconductor material is co-doped and is initially N-type, i.e. it comprises over the whole thickness a doping which is for the major part N-type and a minority P-type doping, the concentration of P-type dopants being comprised between 20% and 100% of the concentration of N-type dopants.

One of the surfaces of the block is then doped so as to form the PN junction, second semiconducting area 3 and first semiconducting area 2. In this way, the concentration of P-type doping impurities is identical in the first and second portions, which makes it easier to master the electric field induced in the photovoltaic device.

The photovoltaic cell comprises a plurality of bumps formed on one of the surfaces of the substrate or on the two opposite surfaces of the substrate and configured to connect the cell with the outside.

1-6. (canceled)

7. A photovoltaic device comprising:
a first semiconducting area made of N-doped silicon including N-type doping impurities,
a second semiconducting area made of P-doped silicon and configured to form a PN or PIN junction with the first semiconducting area,
wherein the first semiconducting area comprises a concentration of P-type doping impurities that is at least equal to 20% of a concentration of the N-type doping impurities.

8. The device according to claim 7, wherein the f first semiconducting area made of N-doped silicon is doped by at least a first doping impurity chosen from Ga, In, Al, Ti, the first semiconducting area made of N-doped silicon being devoid of boron.

9. The device according to claim 7, wherein the first semiconducting area made of N-doped silicon is doped by at least a second doping impurity chosen from P, As, Sb, Li.

10. The device according to claim 7, comprising a monoblock semiconductor element inside which the first semiconducting area made of N-doped silicon and the second semiconducting area made of P-doped silicon are formed.

11. The device according to claim 7, wherein the first semiconducting area made of N-doped silicon comprises one or more first portions opening onto a surface and having a concentration of P-type doping impurities that is at least equal to 20% of the concentration of N-type doping impurities and one or more second doped portions opening onto said surface and having a concentration of P-type doping impurities that is less than 20% of the concentration of N-type doping impurities.

12. The device according to claim 11, wherein the concentration of P-type doping impurities is identical in the first and second portions.
